(19) United States
(12) Patent Application Publication
(10) Pub. No.: US 2026/0324211 A1
(43) Pub. Date: Oct. 15, 2026

(54) ORGANIC ELECTRO-LUMINESCENCE DISPLAY DEVICE AND METHOD FOR MANUFACTURING ORGANIC ELECTRO-LUMINESCENCE DISPLAY DEVICE

(71) Applicant: Japan Display Inc., Tokyo (JP)

(72) Inventor: Tatsuya ISHII, Tokyo (JP)

(21) Appl. No.: 19/562,430

(22) Filed: Mar. 10, 2026

(30) Foreign Application Priority Data
Apr. 11, 2025 (JP) 2025-065872

(51) Int. Cl. H10K 59/124; H10K 59/12; H10K 59/35

(52) U.S. Cl. CPC H10K 59/124; H10K 59/1201; H10K 59/352

(57) ABSTRACT

Each of the plurality of pixels of an organic electro-luminescence display device includes a first electrode, a second electrode including a first bottom portion contacting the first electrode, a part of a third electrode arranged on the same layer as the second electrode and spaced apart from the second electrode, an electro-luminescence element contacting the second electrode, a second insulating layer contacting the electro-luminescence element and the second and the third electrodes, a first groove including a second bottom portion extending form a second side surface of the second insulating layer and exposing a part of a surface of the third electrode, and a fourth electrode arranged on the electro-luminescence element and contacting the electro-luminescence element, the second side surface, and the second bottom portion. The first bottom portion is located at a deeper position from an upper surface of the second insulating layer than the second bottom portion.

### CROSS-REFERENCE TO RELATED APPLICATIONS

This application claims the benefit of priority to Japanese Patent Application No. 2025-065872 filed on Apr. 11, 2025, the entire contents of which are incorporated herein by reference.

### FIELD

An embodiment of the present invention relates to an organic electro-luminescence display device and a method for manufacturing the organic electro-luminescence display device.

### BACKGROUND

In recent years, a display device (hereinafter, referred to as an “organic EL display device”) in which a pixel including an organic electroluminescent device (hereinafter, referred to as an “organic EL device”) is formed has been mounted on a smart phone, a camera, or the like. For example, a manufacturing process of the organic EL display device includes forming an organic EL device according to the color to be emitted by a vacuum-deposition method, an ink-jet method, or the like. For example, it is known that the organic EL elements according to the color to be emitted are formed so as to be separated from each other by minute grooves.

### SUMMARY

An organic electro-luminescence display device includes a plurality of pixels arranged in a first direction and a second direction intersecting the first direction. Each of the plurality of pixels includes a first electrode, a first insulating layer arranged on the first electrode, an opening arranged in the first insulating layer, and including a first side surface of the first insulating layer and a first bottom portion extending from the first side surface and exposing a part of a surface of the first electrode, a second electrode arranged on the first insulating layer, and connected to the first insulating layer, the first side surface, and the first bottom portion, a part of a third electrode arranged on the same layer as the second electrode and spaced apart from the second electrode, an electro-luminescence element arranged on the second electrode and the third electrode, and contacting the second electrode, a second insulating layer arranged between the electro-luminescence element and the second electrode, and between the electro-luminescence element and the third electrode, and contacting the electro-luminescence element, the second electrode, and the third electrode, a first groove arranged in the second insulating layer, and including a second side surface of the second insulating layer and a second bottom portion extending from the second side surface and exposing a part of a surface of the third electrode, and a fourth electrode arranged on the electro-luminescence element and contacting the electro-luminescence element, the second side surface, and the third electrode at the second bottom portion. The first bottom portion is arranged in a deeper position from an upper surface of the second insulating layer than the second bottom portion.

A method for manufacturing of electro-luminescence display device including a plurality of pixels arranged in a first direction and a second direction intersecting the first direction, each of the plurality of pixels includes a first electrode, a first insulating layer arranged on the first electrode, an opening arranged in the first insulating layer, and including a first side surface of the first insulating layer and a first bottom portion extending from the first side surface and exposing a part of a surface of the first electrode, a second electrode arranged on the first insulating layer, and connected to the first insulating layer, the first side surface, and the first bottom portion, a part of a third electrode arranged on the same layer as the second electrode and spaced apart from the second electrode, an electro-luminescence element arranged on the second electrode and the third electrode, and contacting the second electrode, a second insulating layer arranged between the electro-luminescence element and the second electrode, and between the electro-luminescence element and the third electrode, and contacting the electro-luminescence element, the second electrode, and the third electrode, a first groove arranged in the second insulating layer, and including a second side surface of the second insulating layer and a second bottom portion extending from the second side surface and exposing a part of a surface of the third electrode, and a fourth electrode arranged on the electro-luminescence element and contacting the electro-luminescence element, the second side surface, and the third electrode at the second bottom portion, wherein the first bottom portion is arranged in a deeper position from an upper surface of the second insulating layer than the second bottom portion, and the method includes forming a first inorganic insulating layer on the second electrode where the second insulating layer is not arranged and on the second insulating layer, forming a second inorganic insulating layer on the first inorganic insulating layer overlapping a part of the third electrode and the second insulating layer, forming a third inorganic insulating layer on the first inorganic insulating layer where the second inorganic insulating layer is not arranged and on a side surface and an upper surface of the second inorganic insulating layer, removing the third inorganic insulating layer on the first inorganic insulating layer where the second inorganic insulating layer is not arranged, the third inorganic insulating layer on the top surface of the second inorganic insulating layer, and a part of the third inorganic insulating layer on the side surfaces of the second inorganic insulating layer to form a sidewall, and forming the first groove using the sidewall.

### BRIEF DESCRIPTION OF DRAWINGS

FIG. 1 is a plan view showing a configuration of an organic EL display device according to a first embodiment.

FIG. 2 is a layout diagram showing an example of a configuration of a pixel according to the first embodiment.

FIG. 3 is a cross-sectional view of the organic EL display device shown in FIG. 1 taken along a line A1-A2.

FIG. 4 is an enlarged cross-sectional view of a part of the organic EL display device shown in FIG. 3.

FIG. 5A is a block diagram showing an organic EL display device according to a second embodiment of the present invention.

FIG. 5B is a block diagram showing the organic EL display device according to the second embodiment of the present invention.

FIG. 6 is a cross-sectional view showing an enlarged cross-sectional structure of a part of a pixel according to an embodiment of the present invention.

FIG. 7 is a cross-sectional view showing an enlarged cross-sectional structure of a part of a pixel according to the second embodiment.

FIG. 8 is a cross-sectional view showing an enlarged cross-sectional structure of a part of the pixel according to the second embodiment.

FIG. 9 is a cross-sectional view showing an enlarged cross-sectional structure of a part of the pixel according to the second embodiment.

FIG. 10 is a cross-sectional view showing an enlarged cross-sectional structure of a part of the pixel according to the second embodiment.

FIG. 11 is a cross-sectional view showing an enlarged cross-sectional structure of a part of the pixel according to the second embodiment.

FIG. 12 is a cross-sectional view showing an enlarged cross-sectional structure of a part of the pixel according to the second embodiment.

FIG. 13 is a cross-sectional view showing an enlarged cross-sectional structure of a part of the pixel according to the second embodiment.

FIG. 14 is a cross-sectional view showing an enlarged cross-sectional structure of a part of the pixel according to the second embodiment.

FIG. 15 is a cross-sectional view showing an enlarged cross-sectional structure of a part of the pixel according to the second embodiment.

FIG. 16 is a cross-sectional view showing an enlarged cross-sectional structure of a part of the pixel according to the second embodiment.

FIG. 17 is a cross-sectional view showing an enlarged cross-sectional structure of a part of the pixel according to the second embodiment.

FIG. 18 is a cross-sectional view showing an enlarged cross-sectional structure of a part of the pixel according to the second embodiment.

### DESCRIPTION OF EMBODIMENTS

Hereinafter, embodiments of the present invention will be described with reference to the drawings and the like. However, the present invention can be implemented in many different aspects, and should not be construed as being limited to the description of the embodiments exemplified below. Further, in order to make the description clearer, the drawings may be schematically represented with respect to the width, thickness, shape, configuration, and the like of each part as compared with the actual embodiment, but the drawings are merely examples, and do not limit the interpretation of the present invention. In addition, in the embodiment of the present invention, the same reference signs (or reference signs denoted by a, b, and the like) are given to elements similar to those already described with respect to the figures already mentioned, and a detailed description thereof may be omitted as appropriate. In addition, it should be noted that the terms “first” and “second” for each element are convenient labels used to distinguish each element, and do not have any further meaning unless otherwise described.

As used herein, in the case where a member or region is referred to as being “above (or below)” another member or region, this includes not only a case where it is directly above (or directly below) the other member or region, unless otherwise limited, but also a case where it is above (or below) the other member or region, that is, a case where another component is included above (or below) the other member or region.

Herein, a first direction D1 intersects a second direction D2, and a third direction D3 intersects the first direction D1 and the second direction D2 (a direction corresponding to a normal direction to a plane D1-D2). For example, the first direction D1, the second direction D2, and the third direction D3 correspond to a direction X (direction x), a direction Y (direction y), and a direction Z (direction z).

In this specification, in the case where the terms “identical”, “same”, and “match” are used, the “identical”, “same”, and “match” may include errors within the scope of the design.

In the present specification, in the case where elements of an organic EL display device 100 having the same reference signs are to be distinguished from one another, letters of the alphabet are added after the reference signs of the elements having the same reference signs.

### 1. First Embodiment

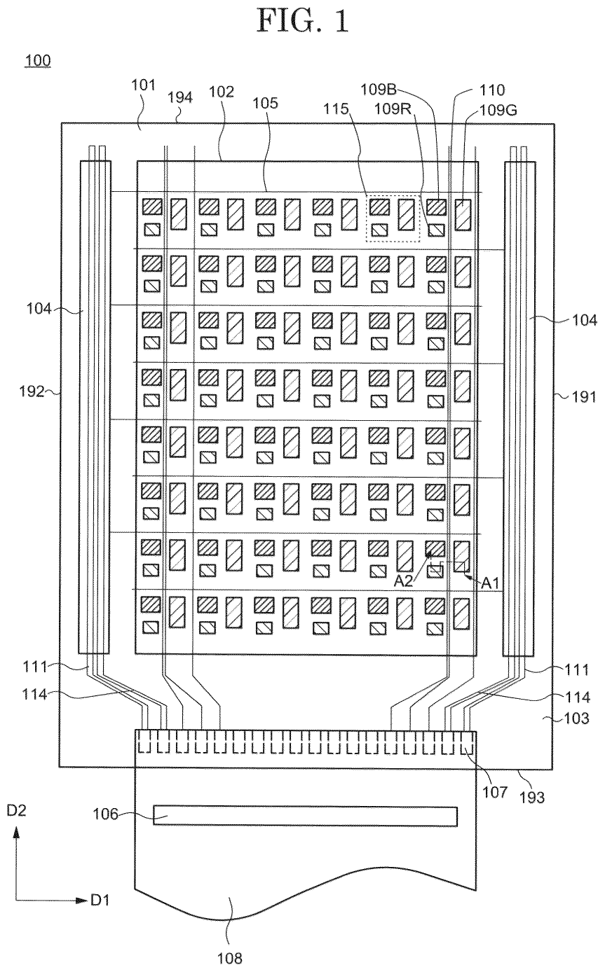

Referring to FIG. 1 to FIG. 4, an overview of the organic EL display device 100 will be described.

### [1-1. Configuration of Organic EL Display Device 100]

FIG. 1 is a schematic diagram showing a configuration of the organic EL display device 100.

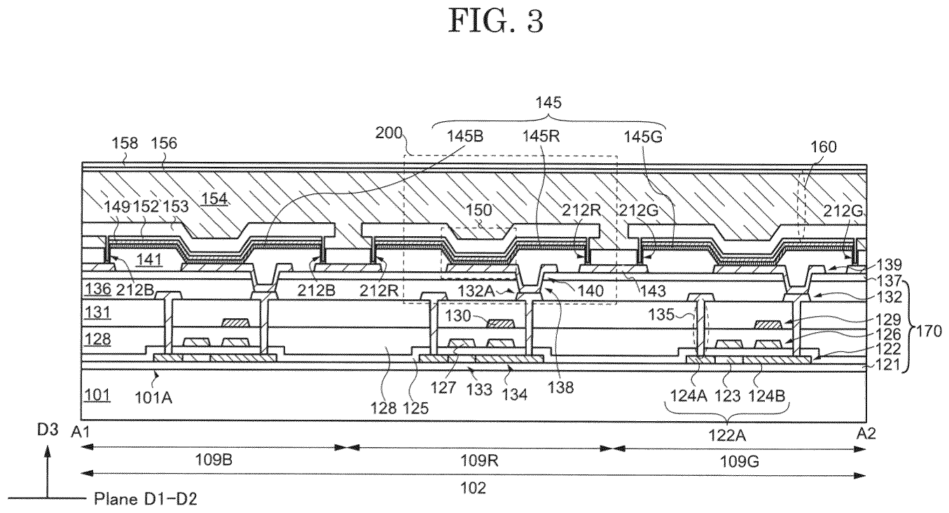

For example, as shown in FIG. 1, the organic EL display device 100 includes a display section 102 and a peripheral section 103 formed on a first surface 101A (see FIG. 3) of a substrate 101. The organic EL display device 100 is surrounded by a first side 191, a second side 192 opposed to the first side, a third side 193, and a fourth side 194 opposed to the third side in a plan view. The peripheral section 103 surrounds the display section 102. In the peripheral section 103, a scanning signal line drive circuit 104 is arranged in a vicinity of the first side 191 and in a vicinity of the second side 192, and a terminal section is arranged in a vicinity of the third side 193. The terminal section includes a plurality of terminals 107. The plurality of terminals 107 is arranged along the first direction D1 (row direction) and is arranged on a lower side of the display section 102 along the second direction D2 (column direction). A plurality of pixels 115 is arranged in the display section 102.

A flexible printed circuit board 108 is connected to the terminal section (the plurality of terminals 107). A driver IC 106 is arranged on the flexible printed circuit board 108 using a COF (Chip on Film) method. The driver IC 106 may be arranged on the flexible printed circuit board 108 using a COG (Chip on Glass) method.

For example, the driver IC 106 may include a video line driver. In the present embodiment, the driver IC 106 or the scanning signal line drive circuit 104 may be referred to as a control circuit or a control section alone, and the driver IC 106 and the scanning signal line drive circuit 104 may be collectively referred to as a control circuit or a control section.

A plurality of scanning signal lines 105 is connected to the scanning signal line drive circuit 104. The plurality of scanning signal lines 105 is arranged adjacently to the first direction D1 with respect to the display section 102. The scanning signal line driver 104 is arranged at a position adjacent to the display section 102 in the first direction D1. The plurality of scanning signal lines 105 is electrically connected to the plurality of pixels 115. For example, a plurality of video signal lines 110, a high-potential power supply line 111, and a low-potential power supply line 114 are connected to the plurality of terminals 107. The plurality of video signal lines 110 is arranged to extend in the second direction D2 of the organic EL display device 100. The plurality of video signal lines 110 is electrically connected to the plurality of pixels 115, and is electrically connected to the driver IC 106 via the plurality of terminals 107 and the flexible printed circuit board 108. The high-potential power supply line 111 and the low-potential power supply line 114 are electrically connected to the scanning signal line drive circuit 104. The high-potential power supply line 111 and the low-potential power supply line 114 may be electrically connected to the plurality of pixels 115.

The driver IC 106 supplies a signal (voltage) to the scanning signal line drive circuit 104, the plurality of video signal lines 110, the high-potential power supply line 111, and the low-potential power supply line 114. The plurality of scanning signal lines 105 supplies scanning signals corresponding to the plurality of pixels 115 to the plurality of pixels 115. The plurality of video signal lines 110 supplies video signals from the driver IC 106 in accordance with the video images displayed on the plurality of pixels 115. The high-potential power supply line 111 and the low-potential power supply line 114 supply potentials to the scanning signal line drive circuit 104 and the plurality of pixels 115.

### [1-2. Configuration of Pixel 115]

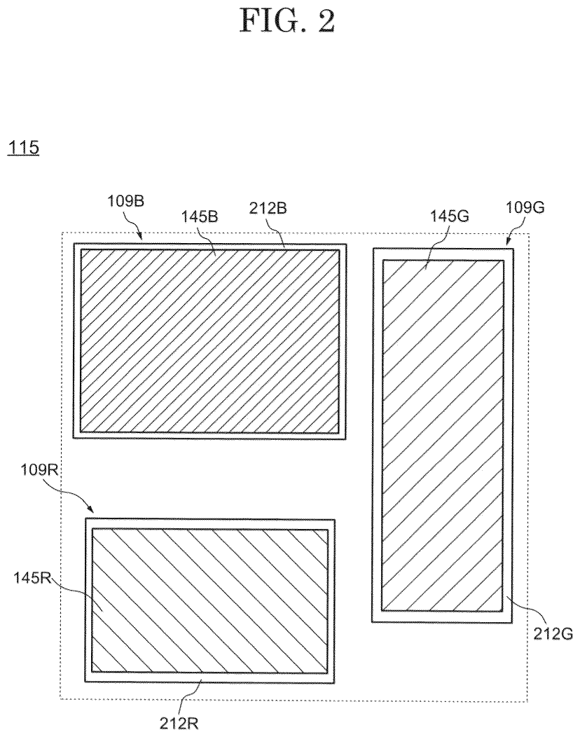

FIG. 2 is a layout diagram showing an exemplary configuration of the pixel 115 included in the organic EL display device 100. The pixels 115 are shown in dashed lines in FIG. 1 and FIG. 2. The dashed line is an imaginary line for simply showing a region of the pixel 115.

As shown in FIG. 1, the plurality of pixels 115 is arranged in a matrix in the first direction D1 and the second direction D2. The pixel 115 includes a sub-pixel 109R, a sub-pixel 109G, and a sub-pixel 109B. For example, the sub-pixel 109R and the sub-pixel 109B are arranged side by side in the second direction D2. The sub-pixel 109B and the sub-pixel 109G and the sub-pixel 109R and the sub-pixel 109G are arranged side by side in the first direction D1. A plurality of sub-pixels 109G is arranged side by side in the second direction D2. That is, in the display section 102, columns in which sub-pixels 109B and sub-pixels 109R are alternately arranged along the second direction D2 and columns in which only the sub-pixels 109G are arranged along the second direction D2 are alternately arranged in the first direction D1 (row direction).

A light-emitting layer 145R, a light-emitting layer 145G, and a light-emitting layer 145B shown in FIG. 2 are light-emitting layers that emit different colors. In a layout of the pixel 115 shown in FIG. 2, a groove 212R and the light-emitting layer 145R included in the sub-pixel 109R, a groove 212G and the light-emitting layer 145G included in the sub-pixel 109G, and a groove 212B and the light-emitting layer 145B included in the sub-pixel 109B are shown, and other elements are omitted. A groove 212 is referred to as a first groove.

For example, the sub-pixel 109R includes the light-emitting layer 145R that emits red light, and includes a red light-emitting element. The sub-pixel 109G includes the light-emitting layer 145G that emits green light, and includes a green light-emitting element. The sub-pixel 109B includes the light-emitting layer 145B that emits blue light, and includes a blue light-emitting element. In the present embodiment, components included in the red light-emitting element are denoted by R (red), components included in the green light-emitting element are denoted by G (green), and components included in the blue light-emitting element are denoted by B (blue).

For example, an emission peak wavelength of the blue light-emitting element is 460 nm or more and 500 nm or less, an emission peak wavelength of the green light-emitting element is 500 nm or more and 570 nm or less, and an emission peak wavelength of the red light-emitting element is 610 nm or more and 780 nm or less.

### [1-3. Cross-Section of Organic EL Display Device 100]

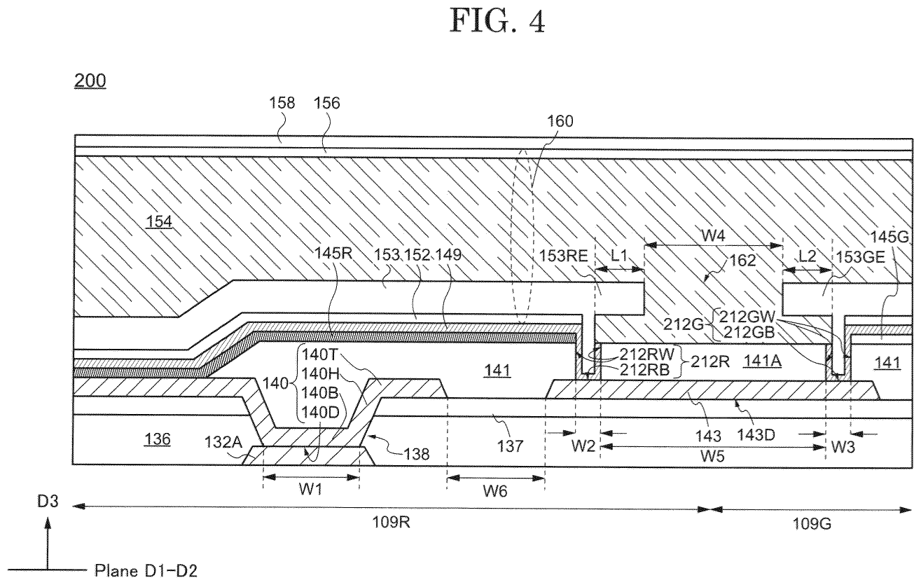

FIG. 3 is a cross-sectional view showing an example of a cross-sectional structure of the organic EL display device 100 shown in FIG. 1 along a line A1-A2, and FIG. 4 is a cross-sectional view showing an example of a cross-sectional structure in which a region 200 shown in FIG. 3 is enlarged. Configurations that are the same as or similar to those in FIG. 1 and FIG. 2 will be described as necessary.

As shown in FIG. 3, a semiconductor layer 122 is arranged on the first surface 101A of the substrate 101 via an underlayer 121. The semiconductor layer 122 includes a channel section 123, a source section 124A, and a drain section 124B. The source section 124A and the drain section 124B may be switched between a function as a source and a function as a drain in accordance with voltages supplied to each other.

On an upper layer of the semiconductor layer 122, a gate insulating layer 125, a conductive layer 126, an insulating layer 128, a conductive layer 129, an insulating layer 131, and a conductive layer 132 are arranged in this order. For example, the conductive layer 126 includes a gate electrode 127 and the scanning signal line 105 (see FIG. 1). For example, the conductive layer 129 includes a capacitor line 130. For example, the conductive layer 132 includes an electrode 132A, the high-potential power supply line 111, the low-potential power supply line 114, and the video signal line 110 (see FIG. 1). For example, the conductive layer 132 is referred to as a first electrode.

The organic EL display device 100 includes a plurality of transistors. For example, each of the plurality of transistors is formed using a semiconductor layer 122A (the channel section 123, the source section 124A, and the drain section 124B), the gate insulating layer 125, and the gate electrode 127. The channel section 123 is a region where the semiconductor layer 122 and the gate electrode 127 overlap each other, and is a region provided between the source section 124A and the drain section 124B. For example, the plurality of transistors includes a transistor 133. The transistor 133 is a transistor for driving the sub-pixel 109R, the sub-pixel 109G, and the sub-pixel 109B included in the sub-pixel 109R, the sub-pixel 109G, and the sub-pixel 109B.

In addition, the organic EL display device 100 may include capacitor elements. For example, a capacitor element 134 is formed using the capacitor line 130 and the semiconductor layer 122 with the gate insulating layer 125 as a dielectric. Further, the capacitor element 134 may be formed using the insulating layer 128 as a dielectric and the capacitor line 130 and the conductive layer 126, and may be formed using the insulating layer 131 as a dielectric and the capacitor line 130 and the conductive layer 132. Further, the capacitor element 134 may be formed using the capacitor line 130 and a layer above the capacitor line 130.

An opening 135 reaching the semiconductor layer 122 is provided in the gate insulating layer 125, the insulating layer 128, and the insulating layer 131. The conductive layer 132 is electrically connected to the semiconductive layer 122, the source section 124A, and the drain section 124B by the opening 135. Further, an opening (not shown) reaching the gate electrode 127 is also provided in the insulating layer 128 and the insulating layer 131, and an opening (not shown) reaching the capacitor line 130 is also provided in the insulating layer 128 and the insulating layer 131.

An insulating layer 136 is arranged to cover the conductive layer 132. An insulating layer 137 may be formed on the insulating layer 136. A conductive layer (not shown) may be formed between the insulating layer 137 and the insulating layer 136, and the capacitor element may be formed using a pixel electrode 140 (a conductive layer 139) and the conductive layer using the insulating layer 137 as a dielectric. An example in which the insulating layer 137 is formed is shown in the example of the organic EL display device 100 shown in FIG. 3. For example, the insulating layer 136 may be referred to as a first insulating layer, and the pixel electrode 140 (the conductive layer 139) may be referred to as a second electrode.

A plurality of openings 138 is provided in the insulating layer 136 and the insulating layer 137. The opening 138 exposes a part of a side wall of the insulating layer 137, a side wall of the insulating layer 136, and the conductive layer 132 (electrode 132A). Accordingly, the opening 138 includes a first bottom portion that exposes a part of the conductive layer 132 (the electrode 132A). In addition, although not shown, the opening 138 exposes a part of the terminal 107. The exposed part of t he terminal 107 is connected to the flexible printed circuit board 108 using a conductive film such as an anisotropic conductive film (not shown).

For example, an array layer 170 includes elements forming transistors and includes the underlayer 121 to the insulating layer 137.

Referring to FIG. 4, each element of layers above the conductive layer 139 will be described. In addition, since the sub-pixels 109R, 109G, and 109B include the same configuration, in the following description of the organic EL display device 100, the configuration of the sub-pixel 109R will be described, and the configurations of the sub-pixels 109G and 109B will be described as necessary.

The conductive layer 139 is provided in an upper layer of the insulating layer 137 and the opening 138. The conductive layer 139 includes the pixel electrode 140. The pixel electrode 140 includes a flat portion 140T, an inclined portion 140H connected to the flat portion 140T, a bottom portion 140B connected to the flat portion 140T and the inclined portion 140H, and a lower surface 140D of the bottom portion 140B. The flat portion 140T is in contact with the insulating layer 137, and the inclined portion 140H and the bottom portion 140B (lower surface 140D) are in contact with the opening 138. In other words, the inclined portion 140H is in contact with the side wall of the insulating layer 137 and the side wall of the insulating layer 136, and the bottom portion 140B (the lower surface 140D) is in contact with the conductive layer 132 (electrode 132A). That is, the opening 138 electrically connects the pixel electrode 140 and the conductive layers 132 (electrode 132A). In the case where the organic EL display device 100 does not include the insulating layer 137, the conductive layer 139 is provided in the upper layer of the insulating layer 136 and the opening 138. The flat portion 140T is in contact with the insulating layer 136, and the inclined portion 140H and the bottom portion 140B (the lower surface 140D) are in contact with the opening 138. In other words, the inclined portion 140H is in contact with the side wall of the insulating layer 136, and the bottom portion 140B (the lower surface 140D) is in contact with the conductive layer 132 (electrode 132A).

A conductive layer 143 is arranged in contact with the insulating layer 137 and spaced apart from the flat portion 140T in the same layer as the flat portion 140T of the pixel electrode 140. The conductive layer 143 includes a lower surface 143D. In the case where the organic EL display device 100 does not include the insulating layer 137, similar to the conductive layer 139, the conductive layer 143 (the lower surface 143D) is in contact with the insulating layer 136.

An insulating layer 141 is arranged to cover a surface and an end portion of the pixel electrode 140 and an end portion of the conductive layer 143. The insulating layer 141 includes an insulating layer 141A, and the insulating layer 141A is arranged on the conductive layer 143. Further, the insulating layer 141 includes the grooves 212R, 212G, and 212B (see FIG. 2 and FIG. 3). The groove 212 is provided between the insulating layer 141A and the insulating layer 141 provided between the sub-pixels. The insulating layer 141 is referred to as a partition wall, a rib, or the like. For example, the insulating layer 141 and the insulating layer 141A may be referred to as a second insulating layer.

A functional layer 145 is arranged so as to cover the conductive layer 139 (the pixel electrode 140) included in the display section 102. A configuration of the functional layer 145 can be selected as appropriate. The functional layer 145 is formed by combining a plurality of layers such as a carrier injection layer, a carrier transport layer, a light-emitting layer, a carrier blocking layer, and an exciton blocking layer. In the organic EL display device 100 shown in FIG. 3 and FIG. 4, only the functional layer 145 (the light-emitting layers 145R, 145G, and 145B) among the plurality of layers is shown.

A region where the conductive layer 139 (pixel electrode 140) and the functional layer 145 are in contact with each other serves as a light emitting portion in each sub-pixel 109R, each sub-pixel 109G, and each sub-pixel 109B.

Although not shown, for example, the functional layer 145 may include a first layer including a carrier (hole) injection and a transport layer, a second layer being the functional layer 145, and a third layer 146 including a carrier (electron) injection and a transport layer. The functional layer 145 is configured to include the sub-pixel 109R, the sub-pixel 109G, and the sub-pixel 109B. As described in the section of “1-2. Configuration of Pixel 115”, in the organic EL display device 100, the sub-pixel 109R includes the light-emitting layer 145R, the sub-pixel 109G includes the light-emitting layer 145G, and the sub-pixel 109B includes the light-emitting layer 145B.

The functional layer 145 is surrounded by the groove 212. Specifically, the light-emitting layer 145R is surrounded by the groove 212R, the light-emitting layer 145G is surrounded by the groove 212G, and the light-emitting layer 145B is surrounded by the groove 212B. The light-emitting layer 145R, the light-emitting layer 145G, and the light-emitting layer 145B are stepped (disconnected) by the groove 212R, the groove 212G, and the groove 212B, and are separated from each other. That is, the groove 212R, the groove 212G, and the groove 212B have a function of suppressing mutual contact between the light-emitting layer 145R, the light-emitting layer 145G, and the light-emitting layer 145B, and protecting the light-emitting layer 145R, the light-emitting layer 145G, and the light-emitting layer 145B from mutual contact.

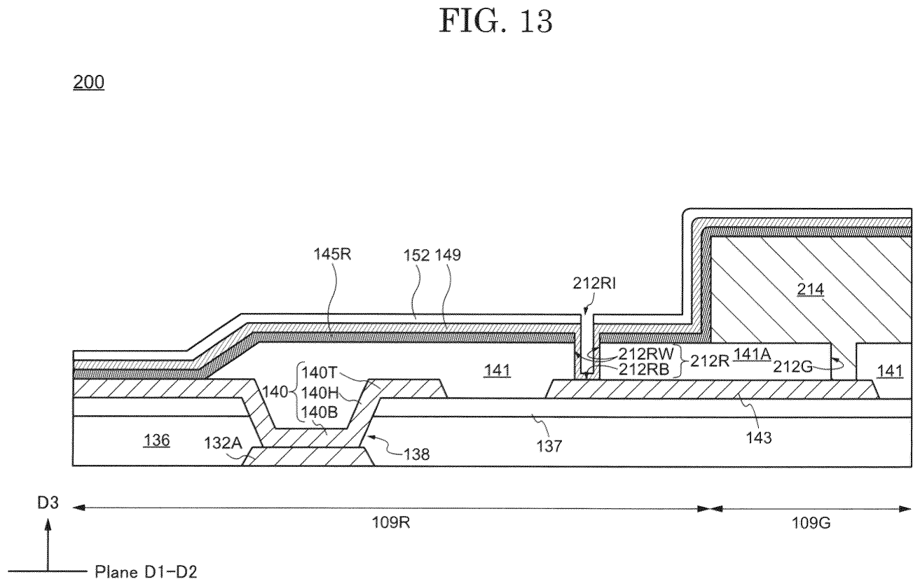

A common electrode 149 is arranged on the functional layer 145 so as to cover the functional layer 145. The common electrode 149 is arranged in the groove 212. The common electrode 149 is not arranged on an upper side (front side) of the insulating layer 141A by the grooves 212 provided in the sub-pixels, is stepped (disconnected), and is separated for each pixel. On the other hand, since the common electrode 149 is arranged in the groove 212, a lower end of the common electrode 149 which is located downward along the third direction D3 is exposed by the groove 212 and is in contact with a surface of the conductive layer 143. For example, a common electrode 149 arranged in the groove 212R is connected to a common electrode 149 arranged in the groove 212G adjacent to the groove 212R via the conductive layer 143. Similarly, the common electrode 149 arranged in the groove 212G is connected to a common electrode 149 provided in the groove 212B adjacent to the groove 212G via the conductive layer 143, and the common electrode 149 provided in the groove 212B is connected to the common electrode 149 provided in the groove 212R adjacent to the groove 212B via the conductive layer 143. In this manner, the common electrode 149 arranged in each sub-pixel is stepped (disconnected) by the groove 212 and separated from each other, but is connected to the conductive layer 143 by being embedded in the groove 212, and is connected to each other via the conductive layer 143. In addition, a groove 212RI (see FIG. 13) is formed by the common electrode 149 embedded in the groove 212. The groove 212RI is referred to as a second groove.

In the organic EL display device 100, a light-emitting element 150 is formed on the insulating layer 137. For example, the light-emitting element 150 includes the pixel electrode 140, a functional layer 148, and the common electrode 149. For example, when the transistor 133 of the sub-pixel 109R is driven, a desired current is supplied to the light-emitting element 150 (the light-emitting layer 145R), and the light-emitting element 150 of the sub-pixel 109R emits red light.

A sealing film 160 is arranged on the light emitting element 150. The sealing film 160 includes an insulating layer 152, an inorganic insulating layer 153, an organic insulating layer 154, and an inorganic insulating layer 156. For example, the insulating layer 152 may be referred to as a third insulating layer, the inorganic insulating layer 153 may be referred to as a fourth inorganic insulating layer, and the inorganic insulating layer 156 may be referred to as a fifth inorganic insulating layer.

The insulating layer 152 is arranged on the common electrode 149. Similar to the functional layer 145, the insulating layers 152 are stepped out for each pixel by the groove 212, and separated from each other for each pixel. The insulating layer 152 is not arranged in the groove 212, but is separated from the groove 212.

The inorganic insulating layer 153 is arranged on the insulating layer 152 and on the common electrode 149. The inorganic insulating layer 153 arranged on the common electrode 149 is embedded in the groove 212RI. The inorganic insulating layer 153 includes an overhang part spaced apart from the insulating layers 141 and 141A. The overhang part includes an overhang part 153RE and an overhang part 153GE. In the cross-sectional view shown in FIG. 3 and FIG. 4, the overhang part extends in the first direction D1 and the second direction D2 from the groove 212, and in a plan view, the overhang part overlaps the common electrode 149 exposed to the insulating layer 141A and a portion of the insulating layer 141A. Further, similar to the insulating layers 152, the inorganic insulating layers 153 are separated from each other for each pixel. For example, the inorganic insulating layer 153 covers the functional layer 145, the common electrode 149, and the insulating layer 152 corresponding to the sub-pixels, and suppresses the functional layer 145, the common electrode 149, and the insulating layer 152 from being unnecessarily exposed to a gas, a solution, or the like at a time of processing the respective layers and disappearing. In addition, positions of the sub-pixels are clarified by positions of the overhang parts 153RE and 153GE of the inorganic insulating layer 153. In addition, although not shown in the drawings, the inorganic insulating layer 153 included in the sub-pixel 109B has an overhang part for the sub-pixel 109B similar to the overhang part 153RE and the overhang part 153GE.

Further, a space 162 is provided (formed) between the overhang part 153RE of the sub-pixel 109R, the overhang part 153GE of the sub-pixel 109G, and the insulating layer 141A between the groove 212R of the sub-pixel 109R and the groove 212G of the sub-pixel 109G.

The organic insulating layer 154 is arranged so as to cover at least the display section 102. Specifically, the organic insulating layer 154 is arranged on (a surface of) the inorganic insulating layer 153 and in the space 162.

The inorganic insulating layer 156 is arranged so as to cover at least the display section 102. Specifically, the inorganic insulating layer 156 is arranged on (a surface of) the organic insulating layer 154. A cover film 158 is arranged on the inorganic insulating layer 156.

As shown in FIG. 4, a width W1 of the bottom portion 140B (the lower surface 140D) of the pixel electrode 140 is the same as a width of a bottom portion of the opening 138. The width W1 is wider than a width W2 of a bottom portion 212RB of the groove 212R and a width W3 of a bottom portion 212GB of the groove 212G. The width W2 may be the same as the width W3. A length L1 extending along the second direction D2 of the overhang part 153RE may be the same as a length L2 extending along the second direction D2 of the overhang part 153GE. A width W5 of the insulating layer 141A is wider than a width W4 between the overhang part 153RE and the overhang part 153GE. That is, the overhang part 153RE and the overhang part 153GE overlap a portion of the insulating layer 141A. In addition, a distance between an end portion of the flat portion 140T of the pixel electrode 140 and an end portion of the conductive layer 143 is a distance W6. Further, the bottom 140B (the lower surface 140D, the bottom portion of the opening 138) of the pixel electrode 140 is arranged below the bottom portion 212RB of the groove 212R and the bottom portion 212GB of the groove 212G along the third direction D3.

For example, a substrate such as a silicon wafer, a sapphire substrate, or the like can be used to form an organic EL device using a substrate sized to enable use of an IC manufacturing process such as a driver IC. In the IC manufacturing process, plugs and micro-grooves can easily be formed that fill the deep openings along the third direction D3. Thus, for example, even if the pixel electrode is arranged above the bottom portion of the fine groove along the third direction D3 and the conductive layer is arranged below the bottom of the fine groove along the third direction D3 and the conductive layer is arranged at a position deeper along the third direction with respect to the pixel electrode, the pixel can be easily miniaturized, a connecting position between the element electrode and the plug is above a position of the bottom portion of the fine groove along the third direction D3, and the pixel electrode can be connected to the pixel electrode and the conductive layer arranged below the fine groove along the third direction D3 via the plug formed in the deep opening.

On the other hand, for example, since a glass substrate is used for the substrate 101 of the organic EL display device 100, it is difficult to form the plug and the fine groove that fill the deep opening along the third direction D3 as formed by the IC manufacturing process. Therefore, in the organic EL display device 100 according to one embodiment of the present disclosure, the pixel electrode 140 is arranged below the bottom 212RB of the groove 212R along the third direction D3, and the conductive layer 132 is arranged at a shallow position below the pixel electrode 140 along the third direction D3. Further, the grooves 212 are formed by sidewalls 206A and 206B formed using inorganic insulating layers 206, which will be described later. Consequently, since the width W1 of the bottom portion 140B (the opening 138) for connecting the flat portion 140T of the pixel electrode 140 and the conductive layer 132 is narrower than the width of the deep opening, and the groove 212 does not depend on a resolution of photolithography, the pixel 115 (sub-pixels 109R, 109G, and 109B) in the organic EL display device 100 can be miniaturized. In addition, the width W1, the width W6, and the like can be adjusted in accordance with the fine grooves 212.

### [1-4. Material of Each Member of Organic EL Display Device 100]

A glass substrate, a quartz substrate, or the like is used as the substrate 101.

For example, the semiconductor layer 122 includes Group 14 elements such as silicon (Si), germanium (Ge), or oxides exhibiting semiconductor properties. For example, the semiconductor layer 122 including the Group 14 element may include crystalline silicon. The crystalline silicon may be low-temperature polysilicon (LTPS) or single-crystal silicon. Further, in the case where the semiconductor layer 122 is made of crystalline silicon, impurities corresponding to a polarity of the transistor are implanted into the source section 124A and the drain section 124B. For example, a metal oxide (oxide semiconductor) having semiconductor characteristics may be included as an oxide exhibiting semiconductor characteristics.

For example, the gate insulating layer 125, the insulating layer 128, the insulating layer 137, the insulating layer 152, the inorganic insulating layer 153, and inorganic insulating layer 156 can use common inorganic insulating layers such as silicone oxide (SiO₂), silicone oxide (SiON), and the like.

An organic compound material selected from acrylic, polyimide, and the like, which has excellent film surface flatness, can be used as the insulating layer 131, the insulating layer 136, and the organic insulating layer 154. The insulating layer 131, the insulating layer 136, the insulating layer 141, and the organic insulating layer 154 cover irregularities caused by transistors and other semiconductor elements, and surfaces of the insulating layer 131, the insulating layer 136, and the organic insulating layer 154 become flat surfaces.

The sealing film 160 suppresses intrusion of impurities (water, oxygen, and the like) from the outside into the light-emitting element 150, the transistor, or the like. Although not shown, for example, the insulating layer 152, the inorganic insulating layer 153, and the inorganic insulating layer 156 are in direct contact with each other around the organic EL display device 100. Consequently, in the organic EL display device 100, the intrusion of impurities from the outside is suppressed.

### 2. Second Embodiment

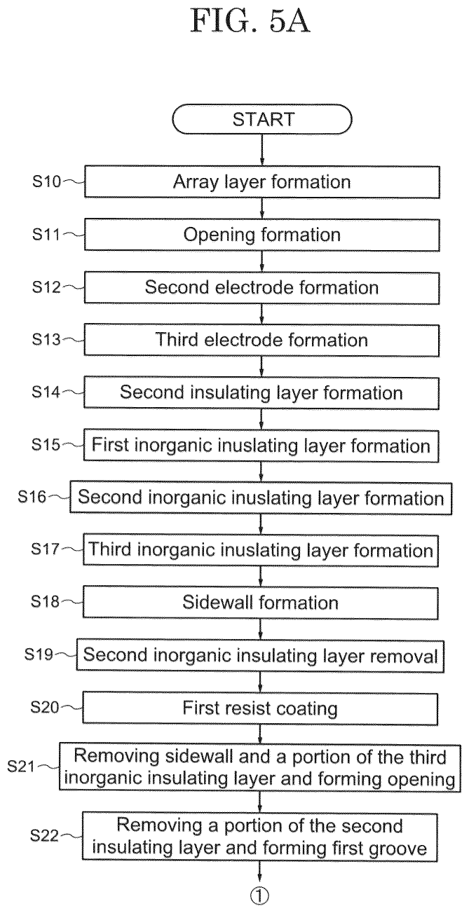

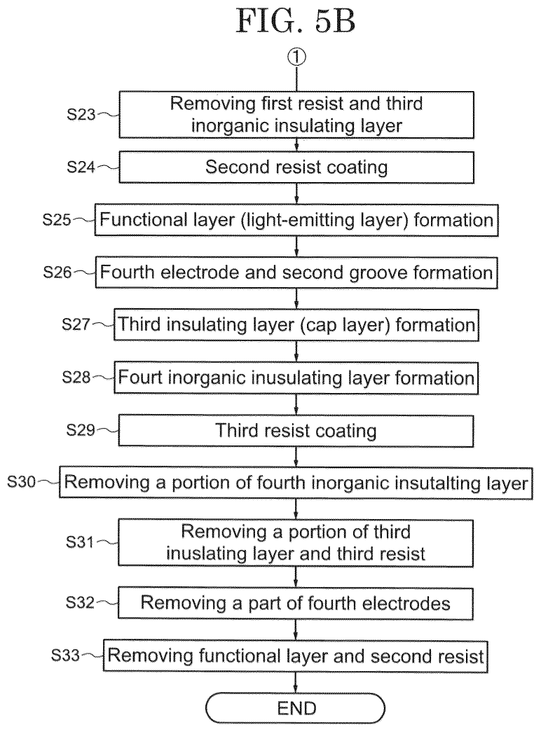

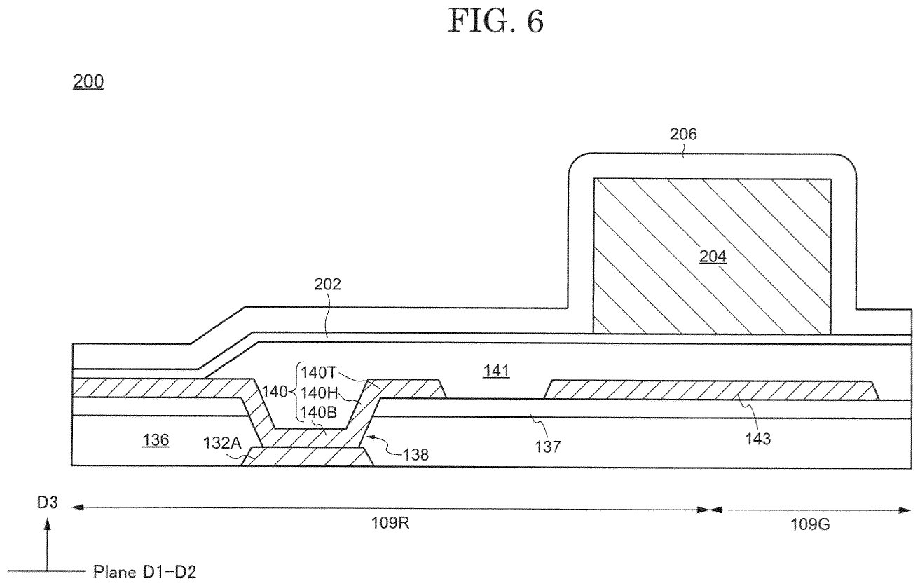

Referring to FIG. 3 to FIG. 18, an outline of a manufacturing process of the organic EL display device 100 will be described. FIG. 5A and FIG. 5B are sequential diagrams showing the manufacturing process of the organic EL display device 100. FIG. 6 to FIG. 18 are cross-sectional views showing an enlarged cross-sectional structure of the region 200 of the pixel 115 occupied in FIG. 2. Configurations that are the same as or similar to those in FIG. 1 to FIG. 4 will be described as necessary.

As shown in FIG. 5A, the array layer 170 is formed (step 10 (S10) in FIG. 5A). Specifically, as shown in FIG. 3, when the manufacture of the organic EL display device 100 is started, the underlayer 121 is formed on the first surface 101A of the substrate 101. The semiconductor layer 122 is formed on the underlayer 121. Impurities are implanted into the semiconductor layer 122 to form the source section 124A and the drain section 124B. The gate insulating layer 125 is formed on the semiconductor layer 122 and on the underlayer 121 where the semiconductor layer 122 is not formed. The conductive layer 126 is formed on the gate insulating layer 125. The conductive layer 126 includes the gate electrode 127. The insulating layer 128 is formed on the conductive layer 126 and on the gate insulating layer 125 where the conductive layer 126 is not formed. The capacitor line 130 is formed on the insulating layer 128. The insulating layer 131 is formed on the capacitor line 130 and on the insulating layer 128 where the capacitor line 130 is not formed. The opening 135 is opened. Each of the openings opens the gate insulating layer 125, the insulating layer 128, or the insulating layer 131 to expose a wiring, a semiconductor layer, or an electrode corresponding to each of the openings. For example, the opening 135 exposes the semiconductor layer 122A (for example, the source section 124A). Other openings also expose corresponding wirings, semiconductor layers, or electrodes. The conductive layer 132 is formed on the insulating layer 131. The conductive layer 132 (first electrode) includes the electrode 132A. For example, the electrode 132A is electrically connected to the semiconductor layer 122 through the opening 135. As shown in FIG. 3, FIG. 4, and FIG. 6, the insulating layers 136 and 137 are formed on the conductive layer 132 and on the insulating layer 131 on which the conductive layer 132 is not formed. As described above, the array layer 170 is formed.

As shown in FIG. 3, FIG. 4, and FIG. 6, the opening 138 is opened (step 11 (S11) in FIG. 5A). Each opening opens the insulating layers 136 and 137 to expose a wiring or electrode corresponding to each opening. For example, the opening 138 exposes the electrode 132A. Other openings also expose corresponding wirings or electrodes.

The pixel electrode 140 is formed on the insulating layer 137 and on the inclined portion of the insulating layer 137, the inclined portion of the insulating layer 136, and the electrode 132A exposed by the opening 138 (step 12 (S12) in FIG. 5A). For example, the pixel electrode 140 is referred to as a second electrode.

The conductive layer 143 is formed on the insulating layer 137 (step 13 (S13 in FIG. 5A). As described in the section of “1-3. Cross-section of Organic EL Display Device 100”, the conductive layer 143 is arranged on the same layer as the flat portion 140T of the pixel electrode 140 so as to be spaced apart from the flat portion 140T. For example, the conductive layer 143 is referred to as a third electrode.

The insulating layer 141 is formed on the pixel electrode 140, on the conductive layer 143, and on the insulating layer 137 on which the pixel electrode 140 and the conductive layer 143 are not formed (step 14 (S14) of FIG. 5A). For example, the insulating layer 141 is an inorganic insulating layer.

An insulating layer 202 is formed on the insulating layer 141 and on the pixel electrode 140 on which the insulating layer 141 is not formed (step 15 (S15) in FIG. 5A). For example, the insulating layer 202 includes silicon nitride (SiN). For example, the insulating layer 202 is referred to as a first inorganic insulating layer.

An insulating layer 204 is formed on a part of the conductive layer 143 and the insulating layer 202 that overlaps the insulating layer 141 (step 16 (S16) in FIG. 5A). For example, the insulating layer 204 includes silicon oxide (SiO₂). For example, the insulating layer 204 is referred to as a second inorganic insulating layer.

The inorganic insulating layer 206 is formed on the insulating layer 202 on which the insulating layer 204 is not formed and on an upper surface (front surface) and a side surface (side wall) of the insulating layer 204 (step 17 (S17) in FIG. 5A). For example, the inorganic insulating layer 206 includes silicon nitride (SiN). For example, the inorganic insulating layer 206 is referred to as a third inorganic insulating layer.

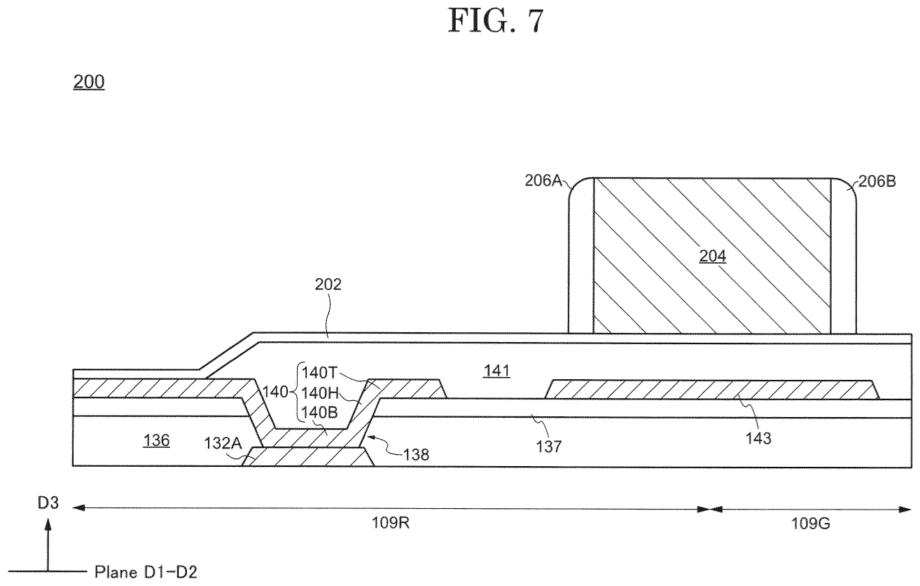

As shown in FIG. 7, the inorganic insulating layer 206 on the insulating layer 202 and the inorganic insulating layer 206 on the upper surface (front surface) of the insulating layer 204 are removed by anisotropic dry etching, a part of the inorganic insulating layer 206 formed on the side surface (side wall) of the insulating layer 204 remains, and the sidewalls 206A and 206B are formed (step 18 (S18) in FIG. 5A).

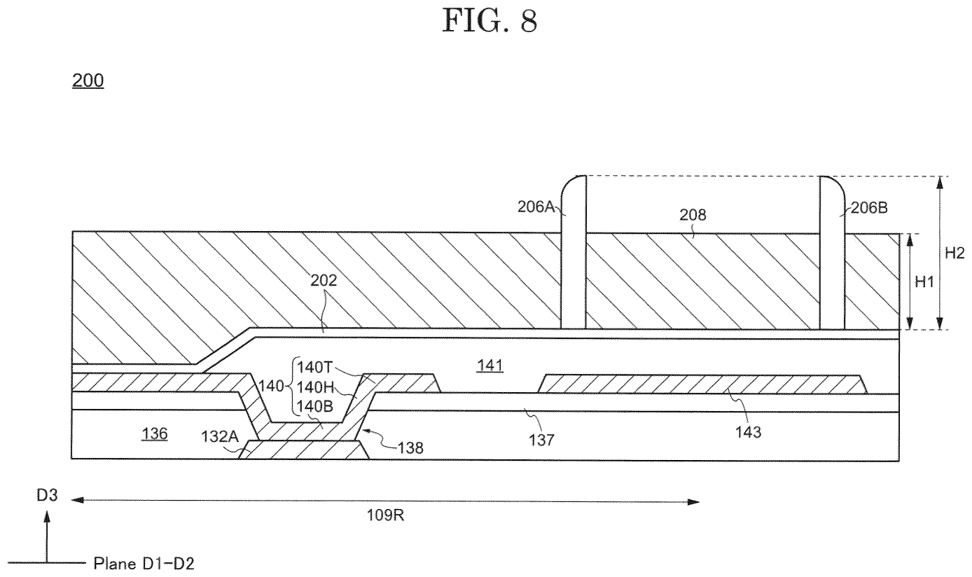

As shown in FIG. 8, the insulating layer 204 is removed (step 19 (S19) in FIG. 5A), and the first resist 208 is applied on the insulating layer 202 on which the sidewalls 206A and 206B are not formed (step 20 (S20) in FIG. 5A). With respect to the surface of the insulating layer 202, a height H1 is adjusted such that a height H2 of the tops of the sidewalls 206A and 206B is higher than the height (thickness) H1 of a surface of a first resist 208. The first resist 208 is a resist having good planarity.

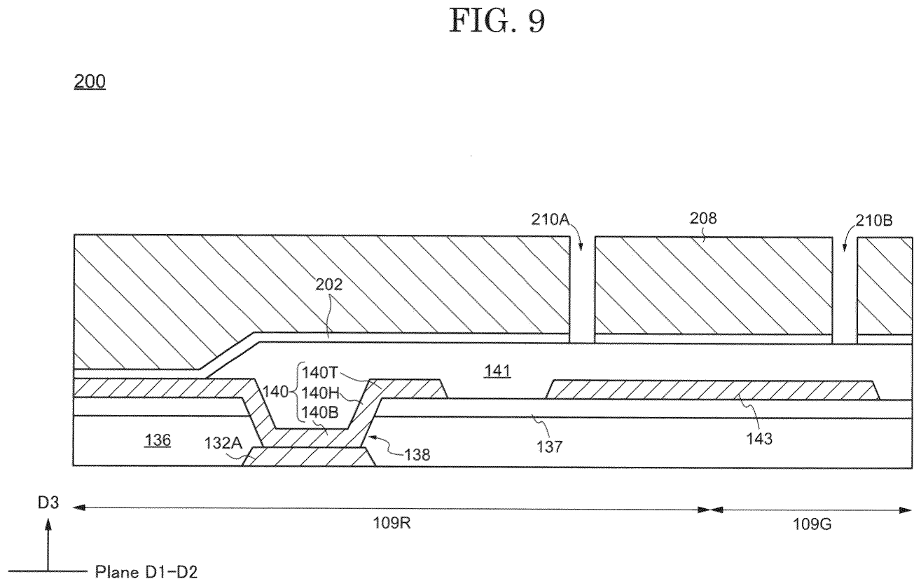

As shown in FIG. 9, the sidewalls 206A and 206B are removed, the insulating layer 202 exposed by the sidewalls 206A and 206B being removed is removed using the first resist 208 as a mask, and openings 210A and 210B are formed (step 21 (S21) of FIG. 5A).

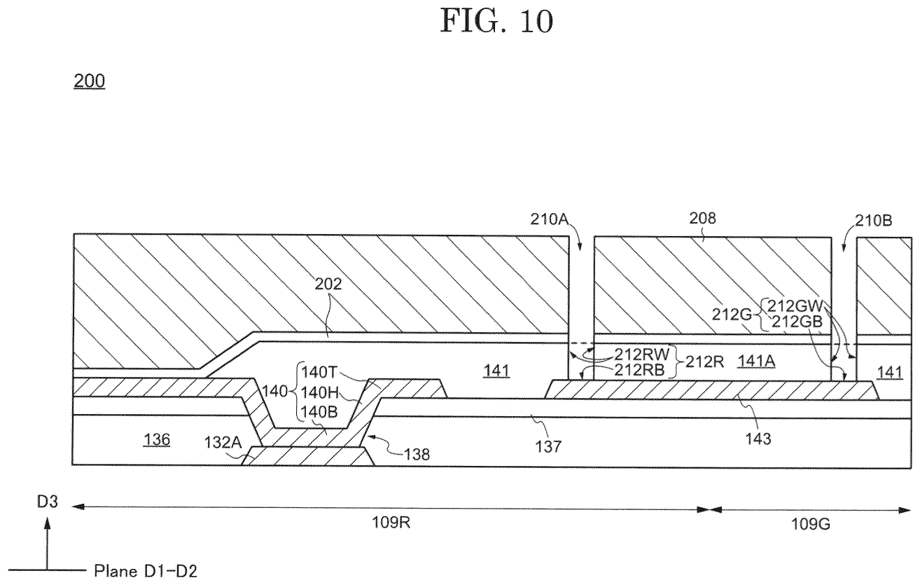

As shown in FIG. 10, using the first resist 208 and the insulating layer 202 as masks, the insulating layer 202 is removed, the exposed insulating layer 141 is removed, and the grooves 212R and 212G exposing a part of the conductive layer 143 are formed (step 22 (S22) in FIG. 5A). For example, the width W2 of the groove 212R and the width W3 of the groove 212G may be 180 nm or more and 220 nm or less. In one embodiment, the width W2 of the groove 212R and the width W3 of the groove 212G are 200 nm.

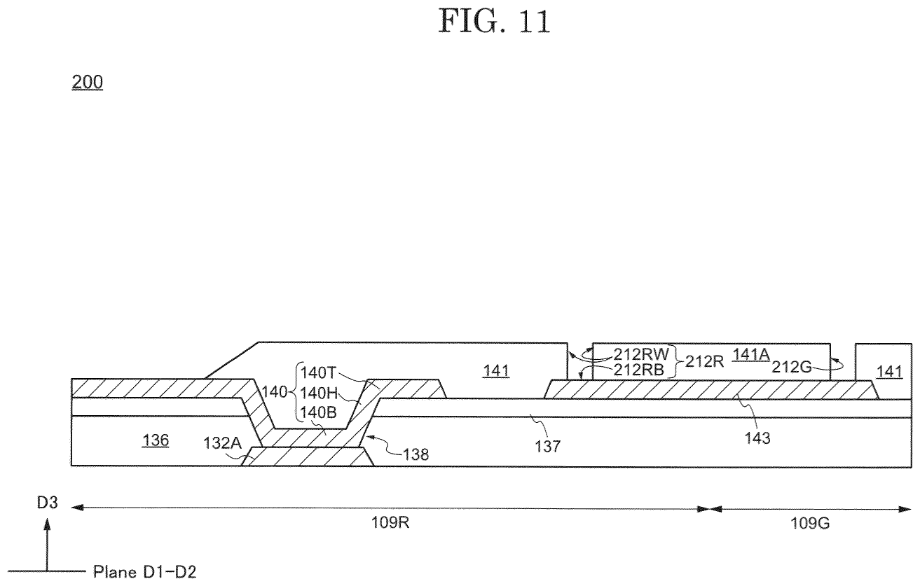

As shown in FIG. 11, the first resist 208 and the insulating layer 202 are removed (step 23 (S23) in FIG. 5B).

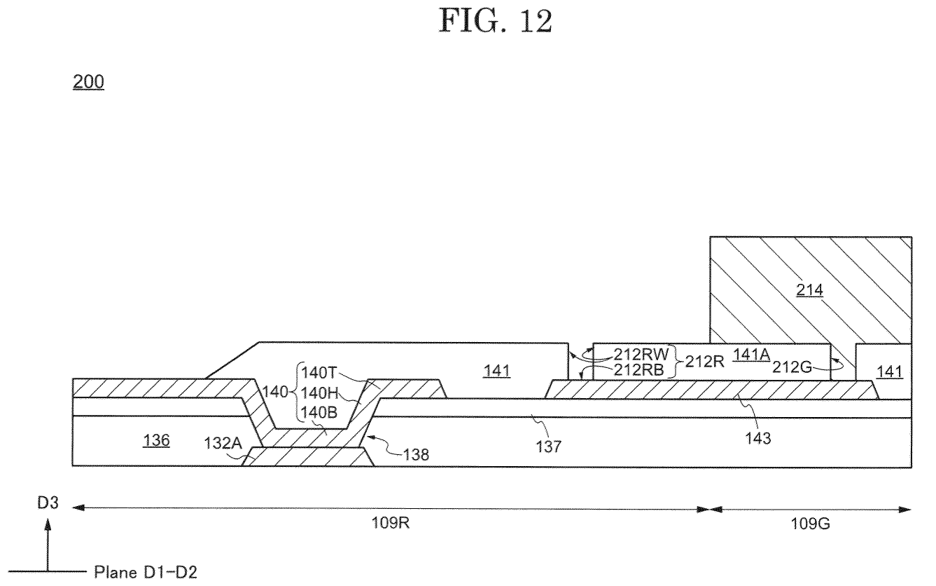

After the grooves 212 are formed, the sub-pixels 109R, the sub-pixels 109G, and the sub-pixels 109B are respectively formed in the same steps. Here, the steps in which the sub-pixel 109R is formed will be described. As shown in FIG. 12, a second resist 214 is applied on a portion of the insulating layer 141 to mask the sub-pixels 109G and 109B other than the sub-pixel 109R (step 24 (S24) in FIG. 5B).

As shown in FIG. 13, the functional layer 145 (here, the light-emitting layer 145R for emitting red light) is formed (step 25 (S25) in FIG. 5B). Since the light-emitting layer 145R is formed by a vapor deposition method, it is not formed at least on the bottom portion 212RB of the groove 212R, but is stepped with the groove 212R as a boundary. That is, the light-emitting layer 145R is formed on the pixel electrode 140 on which the insulating layer 141 is not formed and on the insulating layer 141 on which the second resist 214 is not applied, and is not formed in the groove 212R, and is stepped with the groove 212R as a boundary. Therefore, the light-emitting layer 145R is connected to a part of the flat portion 140T of the pixel electrode 140 and is separated from and not connected to the conductive layer 143. Consequently, for example, as shown in FIG. 3, the groove 212R surrounds the light-emitting layer 145R. In addition, the groove 212G surrounds the light-emitting layer 145G, and the groove 212B surrounds the light-emitting layer 145B.

As shown in FIG. 13, the common electrode 149 is formed on the light emitting layer 145R using a sputtering device, and the groove 212RI is formed (step 26 (S26) in FIG. 5B). Specifically, the common electrode 149 is formed using a sputtering device, so that the common electrode 149 is embedded in an upper surface and a side surface of the light-emitting layer 145R and a side wall 212RW and the bottom portion 212RB of the groove 212R. Consequently, the common electrode 149 is connected to a portion of the conductive layer 143 exposed by the groove 212R. The groove of the common electrode 149 formed inside the groove 212R reflecting a shape of the groove 212R is the groove 212RI. For example, the common electrode 149 is referred to as a fourth electrode.

As shown in FIG. 13, the insulating layer 152 is formed (step 27 (S27) in FIG. 5B). Since the insulating layer 152 is formed by a vapor deposition method as in the case of the light-emitting layer 145R, it is not formed at least at the bottom portion of the groove 212RI, but is stepped with the groove 212RI as a boundary. That is, the insulating layer 152 is formed on the common electrode 149 other than the groove 212RI and is not formed in the groove 212RI, but is stepped with the groove 212RI as a boundary. Thus, the insulating layer 152 is separated from the conductive layer 143. The insulating layer 152 is a so-called cap layer for protecting the common electrode 149 and the light-emitting layer 145R.

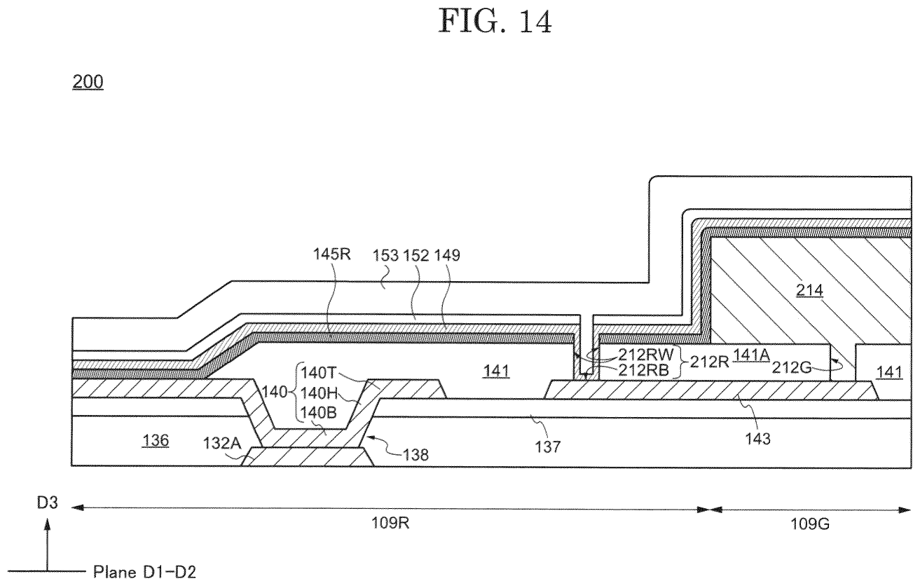

As shown in FIG. 14, the inorganic insulating layer 153 is formed in (inside of) the groove 212RI and on (the surface of) the insulating layer 152 (step 28 (S28) in FIG. 5B).

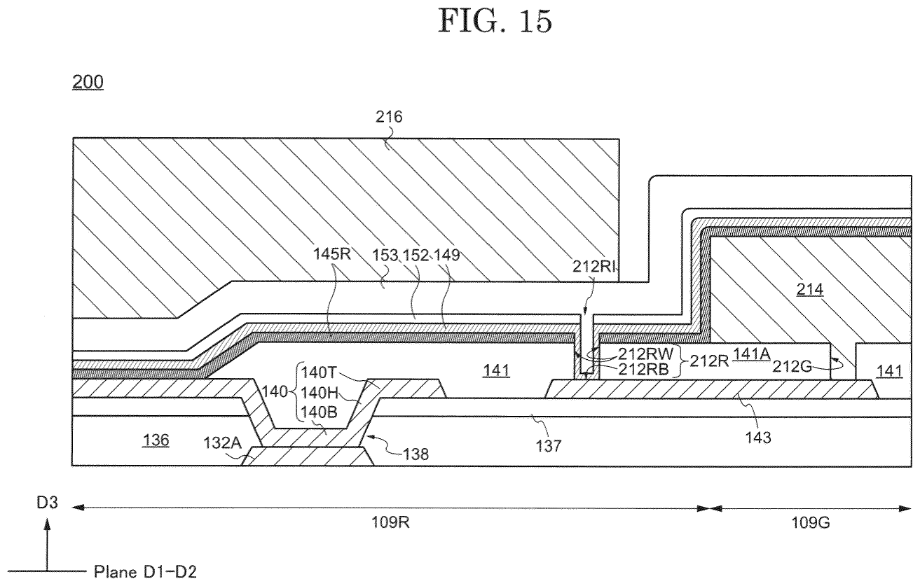

As shown in FIG. 15, a third resist 216 is formed on (a surface of) a portion of the insulating layer 152 (step 29 (S29) in FIG. 5B).

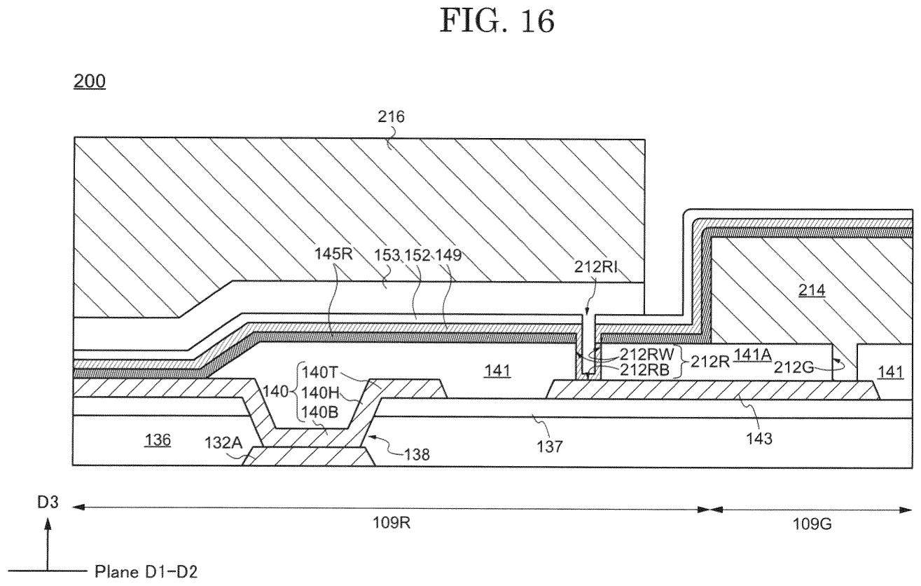

As shown in FIG. 16, the inorganic insulating layer 153 excluding the part of the inorganic insulating layer 153 overlapping the third resist 216 is removed by, for example, anisotropic dry etching (step 30 (S30) in FIG. 5B). In S30, a part of the inorganic insulating layer 153, that is, the inorganic insulating layer not overlapping the third resist 216 is removed.

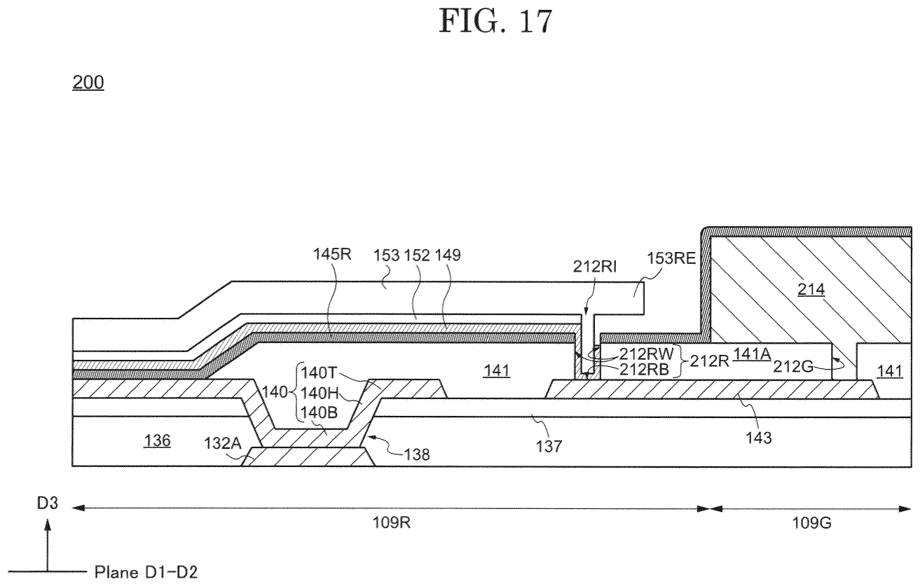

For example, as shown in FIG. 17, of the insulating layers 152, the insulating layer 152 that extends along the first direction D1 and the second direction D2 further than the insulating layer 152 formed in the groove 212RI is removed by, for example, an oxygen-plasma treatment (step 31 (S31) in FIG. 5B) in the case where the insulating layer 152 is an organic insulating layer. In this case, the third resist 216 is also removed simultaneously by the oxygen plasma. In S31, the third resist 216 and a portion of the insulating layer 152, that is, the insulating layer 152 that does not overlap the third resist 216 and the insulating layer 152 below the overhang part 153RE of the inorganic insulating layer 153 are removed along the third direction D3.

As shown in FIG. 17, of the common electrodes 149, the common electrodes 149 extending along the first direction D1 and the second direction D2 further than the insulating layer 152 formed in the groove 212RI and excluding the common electrode 149 between the insulating layer 141A and the groove 212RI are removed by, for example, dry etching (step 32 (S32) in FIG. 5B). In S32, a part of the common electrodes 149, that is, the common electrodes 149 that do not overlap the inorganic insulating film 153 and the common electrode 149 between the overhang part 153RE and the groove 212R of the inorganic insulating layer 153 are removed along the third direction D3.

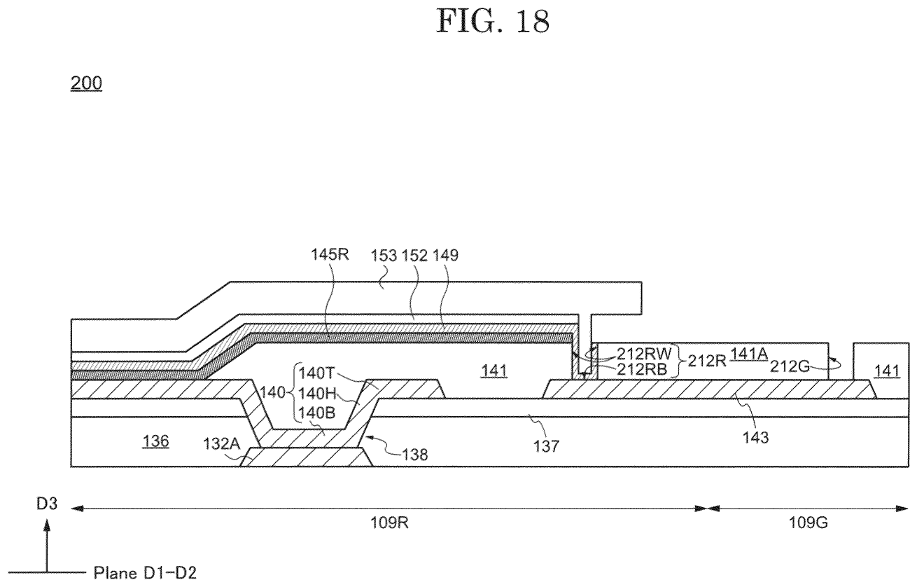

As shown in FIG. 18, of the light-emitting layers 145R, the light-emitting layer 145R extending along the first direction D1 and the second direction D2 further than the insulating layer 152 formed in the groove 212RI and the second resist 214 are removed by, for example, an oxygen plasma treatment (step 33 (S33) in FIG. 5B). Consequently, the overhang part 153RE (see FIG. 17) is formed.

S24 to S33 forms a structure up to the inorganic insulating layer 153 in the sub-pixel 109R. Similar to the sub-pixel 109R, by repeating S24 to S33, the sub-pixel 109G and the sub-pixel 109B are structured up to the inorganic insulating layers 153.

As shown in FIG. 3 and FIG. 4, after S33, the organic insulating layer 154 is formed on the space 162 between the overhang part 153RE and the insulating layer 141A arranged below the overhang part 153RE and the inorganic insulating layer 153 along the third direction D3. After the organic insulating layer 154 is formed, the inorganic insulating layer 156 and the cover film 158 are formed. As described above, the organic EL display device 100 is formed.

The organic EL display device 100 is formed by the manufacturing method described above. The method for manufacturing the organic EL display device 100 includes forming the pixel electrode 140 so as to be arranged below the bottom 212RB of the groove 212R along the third direction D3, and forming the conductive layer 132 at a shallow position below the pixel electrode 140 along the third direction D3. The method for manufacturing the organic EL display 100 includes forming the grooves 212 by the sidewalls 206A and 206B formed using the inorganic insulating layer 206. Consequently, in the method for manufacturing the organic EL display device 100, the width W1 of the bottom portion 140B (the opening 138) for connecting the flat portion 140T of the pixel electrode 140 and the conductive layer 132 can be formed to be narrower than the width of the opening formed deeper, the width W2 and the width W3 of the groove 212 independent of the resolution of photolithography can be formed, and the pixel 115 (the sub-pixels 109R, 109G, and 109B) can be miniaturized.

As the embodiment of the present invention, each of the embodiments described above or a part of each of the embodiments described above can be appropriately combined as long as they do not conflict with each other.

It is to be understood that the present invention provides other functional effects that are different from the operational effects provided by the aspects of the embodiments described above, and those that are obvious from the description of the present specification or those that can be easily predicted by a person skilled in the art.

What is claimed is:

1. An organic electro-luminescence display device comprising a plurality of pixels arranged in a first direction and a second direction intersecting the first direction,
each of the plurality of pixels including:
a first electrode;
a first insulating layer arranged on the first electrode;
an opening arranged in the first insulating layer, and including a first side surface of the first insulating layer and a first bottom portion extending from the first side surface and exposing a part of a surface of the first electrode;
a second electrode arranged on the first insulating layer, and connected to the first insulating layer, the first side surface, and the first bottom portion;
a part of a third electrode arranged on the same layer as the second electrode and spaced apart from the second electrode;
an electro-luminescence element arranged on the second electrode and the third electrode, and contacting the second electrode;
a second insulating layer arranged between the electro-luminescence element and the second electrode, and between the electro-luminescence element and the third electrode, and contacting the electro-luminescence element, the second electrode, and the third electrode;
a first groove arranged in the second insulating layer, and including a second side surface of the second insulating layer and a second bottom portion extending from the second side surface and exposing a part of a surface of the third electrode; and
a fourth electrode arranged on the electro-luminescence element and contacting the electro-luminescence element, the second side surface, and the third electrode at the second bottom portion,
wherein the first bottom portion is arranged in a deeper position from an upper surface of the second insulating layer than the second bottom portion.

2. The organic electro-luminescence display device according to claim 1, wherein a width of the first bottom portion is wider than a width of the second bottom portion.

3. The organic electro-luminescence display device according to claim 1, wherein the second electrode includes a flat portion extending from the first bottom portion, and the electro-luminescence element is in contact with the flat portion.

4. The organic electro-luminescence display device according to claim 1, further comprising:
a third insulating layer arranged on the fourth electrode; and
a fourth inorganic insulating layer arranged on the third insulating layer and a second groove arranged in the fourth electrode.

5. The organic electro-luminescence display device according to claim 4, wherein the electro-luminescence element and the third insulating layer are arranged spaced apart from the second bottom portion.

6. The organic electro-luminescence display device according to claim 4, wherein the fourth inorganic insulating layer includes an overhang part, and the overhang part extends from the first groove in the second direction in a cross-sectional view.

7. The organic electro-luminescence display device according to claim 4, wherein each of the plurality of pixels includes at least a first subpixel and a second subpixel.

8. The organic electro-luminescence display device according to claim 7, wherein the electro-luminescence element of the first subpixel and the electro-luminescence element of the second subpixel emit light of different colors, are surrounded by the first groove and the second groove which are different from each other, and are spaced apart from each other.

9. The organic electro-luminescence display device according to claim 7, wherein the fourth electrode of the first subpixel is connected to the fourth electrode of the second subpixel via the third electrode of the first subpixel and the third electrode of the second subpixel.

10. The organic electro-luminescence display device according to claim 7, further comprising an organic insulating layer,
wherein the second insulating layer is arranged between the first groove of the first subpixel and the first groove of the second subpixel,
the overhang part of the first subpixel is spaced apart from the overhang part of the second subpixel, and
the organic insulating layer is arranged in a space between the overhang part of the first subpixel, the overhang part of the second subpixel, and the second insulating layer between the first groove of the first subpixel and the first groove of the second subpixel, and on the fourth inorganic insulating layer.

11. A method for manufacturing of electro-luminescence display device comprising a plurality of pixels arranged in a first direction and a second direction intersecting the first direction,
each of the plurality of pixels including:
a first electrode;
a first insulating layer arranged on the first electrode;
an opening arranged in the first insulating layer, and including a first side surface of the first insulating layer and a first bottom portion extending from the first side surface and exposing a part of a surface of the first electrode;
a second electrode arranged on the first insulating layer, and connected to the first insulating layer, the first side surface, and the first bottom portion;
a part of a third electrode arranged on the same layer as the second electrode and spaced apart from the second electrode;
an electro-luminescence element arranged on the second electrode and the third electrode, and contacting the second electrode;
a second insulating layer arranged between the electro-luminescence element and the second electrode, and between the electro-luminescence element and the third electrode, and contacting the electro-luminescence element, the second electrode, and the third electrode;
a first groove arranged in the second insulating layer, and including a second side surface of the second insulating layer and a second bottom portion extending from the second side surface and exposing a part of a surface of the third electrode; and
a fourth electrode arranged on the electro-luminescence element and contacting the electro-luminescence element, the second side surface, and the third electrode at the second bottom portion,
wherein the first bottom portion is arranged in a deeper position from an upper surface of the second insulating layer than the second bottom portion, and
the method comprising:
forming a first inorganic insulating layer on the second electrode where the second insulating layer is not arranged and on the second insulating layer;
forming a second inorganic insulating layer on the first inorganic insulating layer overlapping a part of the third electrode and the second insulating layer;
forming a third inorganic insulating layer on the first inorganic insulating layer where the second inorganic insulating layer is not arranged and on a side surface and an upper surface of the second inorganic insulating layer;
removing the third inorganic insulating layer on the first inorganic insulating layer where the second inorganic insulating layer is not arranged, the third inorganic insulating layer on the top surface of the second inorganic insulating layer, and a part of the third inorganic insulating layer on the side surfaces of the second inorganic insulating layer to form a sidewall; and
forming the first groove using the sidewall.

12. The method for manufacturing an organic electro-luminescence display device according to claim 11,
wherein the formation of the first groove using the sidewall includes:
removing the second inorganic insulating layer after forming the sidewall;
applying a first resist to the first inorganic insulating layer excluding the first inorganic insulating layer on which the sidewall is formed;
removing the sidewall;
removing the first inorganic insulating layer exposed by removing the sidewall;
removing the second insulating layer exposed by removing the first inorganic insulating layer; and
exposing a part of the third electrode by removing the second insulating layer.

13. The method for manufacturing an organic electro-luminescence display device according to claim 12, further comprising:
after forming the first groove,
applying a second resist to a part of the second insulating layer;
forming the electro-luminescence element on the second electrode excluding the part of the second electrode on which the second insulating layer is arranged and on the second insulating layer excluding the part of the second insulating layer on which the second resist is applied and connecting a part of the flat portion of the second electrode to a part of the electro-luminescence element;
forming the fourth electrode on the electro-luminescence element, the second side surface, and the second bottom portion and connecting the fourth electrode to the exposed part of the third electrode;
forming the fourth electrode to form a second groove;
forming a third insulating layer on the fourth electrode; and
forming a fourth inorganic insulating layer inside the second groove and on the third insulating layer.

14. The method for manufacturing an organic electro-luminescence display device according to claim 13,
wherein the formation of the electro-luminescence element includes forming the electro-luminescence element spaced apart from the third electrode, and the formation of the third insulating layer includes forming the third insulating layer spaced apart from the third electrode.

15. The method for manufacturing an organic electro-luminescence display device according to claim 14, further comprising:
after forming the fourth inorganic insulating layer,
applying a third resist onto the fourth inorganic insulating layer;
removing the fourth inorganic insulating layer excluding the part of the fourth inorganic insulating layer overlapping the third resist;
removing the third insulating layer extending from the fourth inorganic insulating layer formed in the second groove in the first and second directions;
removing the fourth electrode extending from the fourth inorganic insulating layer formed in the second groove in the first and second directions excluding the fourth electrode between the second insulating layer and the second groove;
removing the electro-luminescence element extending from the fourth inorganic insulating layer formed in the second groove in the first and second directions; and
forming an overhang part.

16. The method for manufacturing an organic electro-luminescence display device according to claim 15,
wherein the first groove and the second groove are formed to surround the electro-luminescence element.

17. The method for manufacturing an organic electro-luminescence display device according to claim 14, further comprising forming an organic insulating layer in a space between an overhang part and the second insulating layer arranged below the overhang part along a third direction, and on the fourth inorganic insulating layer.

18. The method for manufacturing an organic electro-luminescence display device according to claim 11, further comprising:
forming the first electrode;
forming the first insulating layer on the first electrode;
forming an opening on the first insulating layer, the opening including the first side surface and the first bottom portion extending from the first side surface and exposing a part of the surface of the first electrode;
forming the second electrode on the first insulating layer, the second electrode contacting the first insulating layer, the first side surface, and the first electrode at the first bottom portion; and
forming the third electrode on the same layer as the flat portion of the second electrode, spaced apart from the second electrode,
wherein the first bottom portion is arranged at a deeper position from the upper surface of the second insulating layer than the second bottom portion.

19. The method for manufacturing an organic electro-luminescence display device according to claim 12,
wherein a width of the first bottom portion is wider than a width of the second bottom portion.
